(19) United States
(12) Patent Application Publication
(10) Pub. No.: US 2012/0123708 A1
(43) Pub. Date: May 17, 2012

(54) METHOD AND SYSTEM FOR TRANSIENT AND INTERMITTENT EARTH FAULT DETECTION AND DIRECTION DETERMINATION IN A THREE-PHASE MEDIAN VOLTAGE ELECTRIC POWER DISTRIBUTION SYSTEM

(76) Inventors: Xinzhou Dong, Beijing (CN); Tao Cui, Beijing (CN); Zhiqian Bo, Holloway Bath (GB); Andrzej Klimek, Surrey (CA); Andrzej Juszczyk, Wakvrztch (PL)

(21) Appl. No.: 13/263,310

(22) PCT Filed: May 15, 2009
(86) PCT No.: PCT/EP09/55954

§ 371 Date: Dec. 20, 2011

(30) Foreign Application Priority Data
Apr. 10, 2009 (CN) 200910131630.1

(51) Int. Cl. G06F 19/00; G01R 31/02

(52) U.S. Cl. 702/58

(57) ABSTRACT

A method and a system for transient and intermittent earth fault detection and direction determination in a three-phase median voltage electric power distribution system which comprises many lines. The system comprises: sampling means wherein the residual current and residual voltage on said lines are sampled, transient direction detection means based on instantaneous power, random intermittent detection means based on intermittent change of residual current amplitude, means of integrating transient direction and random intermittent detection, and alarm means indicating maintenance personnel to check the status of one line.

### BACKGROUND OF THE INVENTION

1. Field of the Invention

This invention relates to a method and a system for transient and intermittent earth fault detection and direction determination in a three-phase median voltage electric power distribution system.

2. Description of the Related Art

The technical field is power system protection and control. The invention is related to the detection of transient/intermittent single phase to ground faults and determination of the earth faults directions in a three-phase median voltage (10 kV-35 kV) electric power distribution system. A transient event refers to a disturbance that only lasts for a short time within one power cycle or several power cycles. An intermittent event refers to a series of transient events, which is a typical feature of arcing fault and high impedance fault in relative short time duration (several seconds).

Conventional detection methods are mainly based on phasor and Fourier results. Therefore, these methods are actually targeting at steady sinusoid signals. However said results may be inaccurate, even incorrect if the event lasts for less than half a cycle. In fact, there are abundant transient information that could be used for fault detection, but the Fourier transform actually filters out these high frequency components. Therefore, conventional phasor based methods are not suitable in dealing with transient and non-steady sinusoid signals.

The document referenced [1] at the end of the description describes a system and a method for detecting high-impedance faults in a multi-grounded power distribution system. The fault evaluation is based on a so-called “Sum of Difference current” (SDI) value which is the sum of the cycle to cycle differences of sampled points. Said method, using non-phasor value to detect such fault generated noises, is a simple sum of the increments, with no other usage of the transient information. It may be vulnerable to other noises. Moreover, it has no direction feature.

The document referenced [2] describes a method and an apparatus which are provided for detecting a fault on a power line carrying a line parameter such as a load current. The apparatus monitors and analyzes the load current to obtain an energy value, which is compared to a threshold value. If the energy value is greater than the threshold value a first counter is incremented. If the energy value is greater than a high value threshold or less than a low value threshold then a second counter is incremented. If the difference between two subsequent energy values is greater than a constant then a third counter is incremented. A fault signal is issued if the first counter is greater than a counter limit value and either the second counter is greater than a second limit value or the third counter is greater than a third limit value. Said document focuses on the randomly changes of the amplitude. The direction of an intermittent fault (or selectively alarming the faulted line) is not a necessary concern. Therefore, it is not applicable to a system with a grounding condition other than a solid grounding.

The document referenced [3] describes a method and an apparatus for identification of an intermittent earth fault in an electric distribution network. The intermittent earth fault is identified on the basis of a zero sequence voltage and a sum current of phase currents. The zero sequence voltage and the sum current are filtered so that the filtered zero sequence voltage and the sum current only comprise a transient component appearing in the intermittent earth fault. When the amplitudes of the transient components of said zero sequence voltage and sum current exceed corresponding set values for the amplitude, and when the phase difference between the phase angles of the transient components of said zero sequence voltage and sum current is within a preset value range, the intermittent earth fault is identified as occurring on the observed electricity distribution feeder. Said document bases its principle on the sinusoid signal information, in seeing the phasor feature from the 500 Hz high frequency component. However, to only consider the specified high frequency component often proves to be inaccurate due to the interferences generated by other noises or due to the sampling errors. Also the phase result is often not so stable, the phasor concept is not suitable for the transient scenario.

The document referenced [4] describes a method and a system for protecting an electricity network against restriking earth faults. Said electricity network comprises one or more feeders going out from a supply point and is preferably a three-phase network. The method comprises the steps of detecting an earth contact related to an earth fault in the electricity network, identifying the feeder on which the earth contact occurs by means of current pulses or current pulses and voltage values related to the earth contact. A current value is interpreted as a current pulse at the moment the instantaneous value of the current divided by the effective value of the current exceeds a predetermined limit. The number of detected earth contacts is calculated per each feeder. It is identified that there is a restriking earth fault on the feeder if the number of the detected earth contacts per said feeder exceeds a predetermined number during a predetermined period, or if the number of the detected earth contacts per said feeder exceeds a predetermined number while the voltage between the start point of the electricity network and the earth, i.e. the zero voltage, remains above a predetermined limit. Said document selects the faulty feeder by comparing the polarity of current spikes to the polarity of voltage spikes.

Generally speaking, there are largely existing earth fault phenomena that fall below the reliable detectable level of conventional relays for the protection of distribution feeders. These faults are generally defined within the range of high impedance faults. They are mostly caused by non-metallic or non-steady conducting of the phase to ground fault path: a downed conductor on non-conductive surface, or the intermittently breakdown of poor insulation condition. Therefore, either the impedance in a fault circuit restricts the fault current below the threshold of a fault detector, or the transient conducting restricts the time duration of the fault event and makes the fault undetectable by the conventional protection device. Although these faults may not cause a severe damage to the system, they reveal the defects of the feeders: an intermittent conducting of a transient fault may be a sign of the degradation of the insulation condition along the lines or cables. High impedance fault (HIF) detection is a relatively very active research field. New technologies such as Artificial Intelligent, modern digital signal processing and pattern recognition are all the focuses in the research, however, as a practical improvement for feeder protection, this invention targets at the most distinctive features of HIF and provide a practical algorithm and embodiment that can be easily implemented into a conventional digital feeder relay platform.

Therefore, the invention is focused on such intermittent faults detection or generally on detection of a large catalogue of high impedance faults. So the purpose of the invention method and system is to solve the following problems:

Transient/intermittent earth fault hides below the reliable detectable level of conventional relays, in revealing the defects of a line that should be detected and alarmed for safety and security reasons, making it necessary to increase the sensitivity.

In radially connected distribution system, transient earth fault current also flows on healthy lines due to large distributed line capacitance. Direction method is needed to discriminate the faulty lines from healthy lines. The relay's selectivity needs to be increased.

Conventional phasor based method is not applicable to transient signal computation. Therefore, it cannot give an accurate result when used for direction detection. An accurate direction is an important aspect with respect to security and sensitivity.

Conventional relay is mostly reset in these transient/intermittent situations. Therefore, it ignores these largely existing earth fault phenomena, which should be included in the detection range of the invention method and system.

### SUMMARY OF THE INVENTION

The invention concerns a method for transient and intermittent earth fault detection and direction determination in a three-phase median voltage electric power distribution system which comprises many lines, characterized in that it comprises, for one line, for example one feeder:

a sampling step wherein the residual current and the residual voltage on said line are sampled,

a transient direction detection step based on the instantaneous power,

a random intermittent detection step based on the intermittent change of the residual current amplitude,

a step of integrating transient direction and random intermittent detection, which:
discriminates the spikes on the faulty line from healthy lines by transient direction detection, and
counts the spikes with forward direction within a time window,
compares the counting result at the end of the time window to a specified threshold number,
reports a set of results, the integration enabling random intermittent detection to selectively counting the spikes,

an eventual alarm step indicating maintenance personnel to check the status of said line.

The transient direction step and the random intermittent detection step have the following stages:

a READY stage, when the algorithm keeps monitoring and is ready to be started;

a START stage when the algorithm begins to evaluate the fault; and

an ALARM/RESET stage, occurring when the START stage ends, wherein the result by alarm or reset is given out.

If a transient event is detected by random intermittent detection and transient direction detection at the end of the START stage, further events are expected, and if consecutive three transient events are detected within a reset time duration, an intermittent earth fault is reported.

Advantageously, the instantaneous active or reactive power is used for direction detection.

Advantageously, fault components of residual current and residual voltage are used to calculate the instantaneous power. The Hilbert transform based on instantaneous power is used, the instantaneous active power is obtained by averaging instant residual voltage and residual current's scalar multiplication in previous one cycle time window, while the instantaneous reactive power is obtained by averaging Hilbert transformed instant residual voltage's and residual current's scalar multiplication in previous one cycle time window, the direction discrimination being performed by comparing such instantaneous active power or such instantaneous reactive power to a power threshold.

Advantageously, the method keeps sampling and buffering the samples of the residual current and residual voltage in the normal running stage (READY stage), and these normal samples will be kept in fault evaluation stage (START stage), the fault component being obtained by substracting these normal samples from the full samples in START stage, and the fault components being used for instantaneous power calculation and further direction detection.

Advantageously, in the fault component circuit, assuming the direction from the bus-bar to the feeder is the positive/forward direction, a power threshold is predetermined. If the active instantaneous power is negative and falls below the negative value of power threshold, a forward direction is then issued. If the active instantaneous power is positive and is greater than the positive value of active power threshold, a reverse direction is then issued. If the reactive instantaneous power is positive and greater than the positive reactive power threshold, a forward direction result is then issued. If the reactive instantaneous power is negative and below the negative value of the reactive power threshold then a reverse direction result is issued. Additionally, the instantaneous reactive power is used in neutral point isolated or resistor grounded system, while the instantaneous active power is only used in neutral point Peterson coil grounded system.

Advantageously, the method comprises a fault evaluation step, wherein the direction is given by comparing the calculated instantaneous power with a power threshold, the power threshold being adaptively changing according to the maximum value of the calculated power. The power threshold may be set to a half of the maximum calculated power absolute value: If the instantaneous power value is such that its absolute value is five times greater than the P (Active Power) or Q (Reactive Power)'s current thresholds, half of the greatest instantaneous power absolute value is considered as the new threshold.

Advantageously incremental amplitude is used to detect intermittent spikes, and to initiate fault evaluation, the amplitude being computed by using half-cycle R.M.S. calculation, a spike being a consecutive increase and decrease of residual current incremental amplitude which indicates conducting and extinguishing of a spike. The spike's direction is obtained from transient direction detection step, when fault evaluation is initiated, within a settable detection time, said spikes with forward direction being counted, the results at the end of the fault evaluation time being used to compare to specified thresholds and to subsequently give out a set of fault detection results. Incremental amplitude is obtained by subtracting the average amplitude from the newly calculated amplitude, the average amplitude being obtained by a filter: y(n)=[y(n−1)·(N−1)+x(n)]/N, where y(n) is the average amplitude on a current time point, and represents previous N points amplitude conditions, y(n−1) is the average amplitude of the previous point, x(n) is the newly calculated amplitude. At the end of fault evaluation, if the numbers of spikes counted exceeds a determined level, the result indicates an intermittent fault; if the number of spikes is more than 2 but is below the determined level, a transient event is reported; if the amplitude keeps increasing or remains unchanged without decrease, a steady event is the result; other situations being reported as noises.

The invention also concerns a system for transient and intermittent earth fault detection and direction determination in a three-phase median voltage electric power distribution system which comprises many lines, characterized in that it comprises:

sampling means wherein the residual current and residual voltage on said lines are sampled,

transient direction detection means based on instantaneous power,

random intermittent detection means based on intermittent change of residual current amplitude,

means of integrating a transient direction and random intermittent detection, which:
discriminates the spikes on the faulty lines from healthy lines by transient direction detection, and
counts the spikes with forward direction within a time window,
compares the counting result at the end of the time window to a specified threshold number,
reports a set of results, the integration enabling random intermittent detection to selectively counting the spikes,

alarm means indicating to check the status of one line.

Advantageously, said system comprises:

a module for sampling voltage and current,

a trigger,

an intermittent spike detection module,

a module for adjusting a power threshold of transient direction detection,

an instantaneous power direction module,

a counter,

a module giving out a report.

The invention method and system are using instantaneous power direction that is applicable to non-sinusoid signals. The invention is actually utilizing high frequency components. It can also be implemented at power frequency sampling rate and can be easily integrated into conventional protection devices. Thus, the advantages are:

The instantaneous power is suitable for analyzing the non-sinusoid transient signals.

The instantaneous power can be obtained in a relative lower sampling rate so that the invention method is convenient to be used in conventional digital relay platforms.

The instantaneous reactive power is especially effective when used in a resistor grounded system or isolated system. Said power is only related with system characteristics, therefore it is more robust. The proposed adaptive threshold enables the direction detector to give a definite direction result when a spike has been captured.

Based on the instantaneous power direction, the invention provides a more reliable solution for an isolated or resistor grounded system by using instant reactive power, and a possible solution for Peterson coil grounded system by using instant active power.

The invention makes it possible to respond to transient and intermittent faults, also regarded as high impedance faults or arcing faults, that conventional relays fail to deal with.

The invention makes it possible to selectively alarm on faulty lines.

The invention is applicable in uni-grounded system with different grounding conditions: resistor grounded, Peterson coil grounded or isolated.

### BRIEF DESCRIPTION OF THE DRAWINGS

FIG. 1 shows the configuration of the invention system.

FIG. 2 is the diagram, in the invention system and method organization, of transient direction detection (TDD) and random intermittent detection (RID).

FIG. 3 is the flowchart of transient direction detection.

FIGS. 4A and 4B show the invention direction criteria using instantaneous power.

FIG. 5 is an example of the adaptive threshold setting of transient direction detection.

FIG. 6 is the flowchart of random intermittent detection.

FIGS. 7A-7C and 8A-8C show exemplary results for a preferred implementation of integration of random intermittent detection and transient direction detection.

### DESCRIPTION OF THE PREFERRED EMBODIMENTS

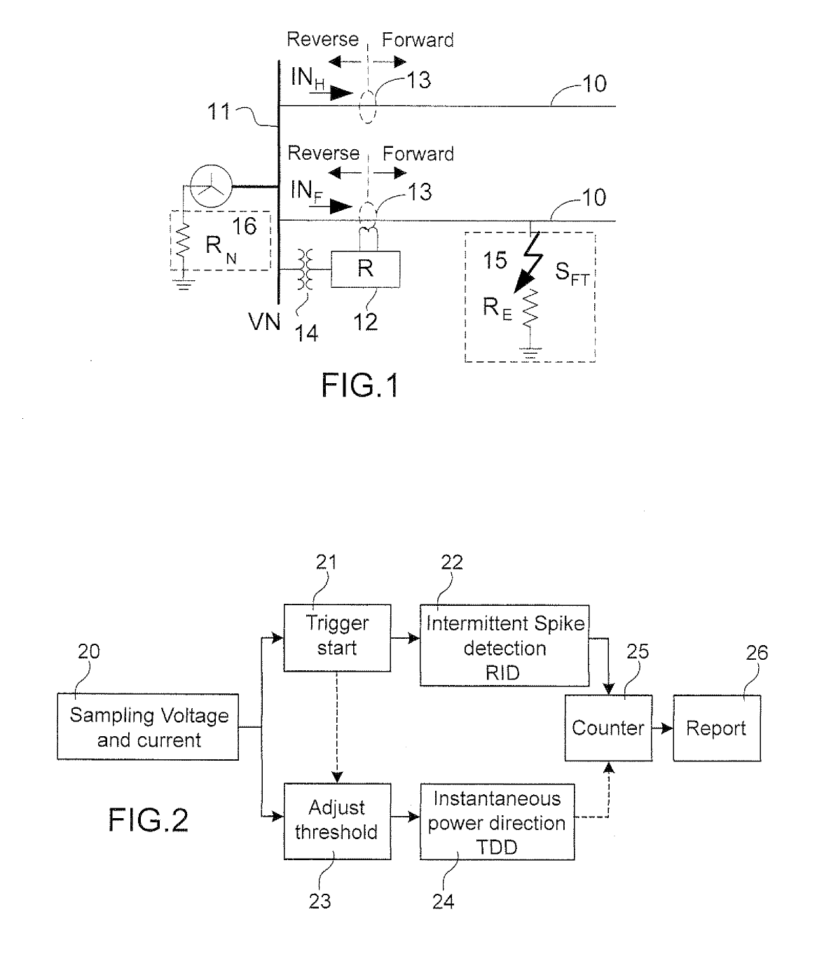

As shown in FIG. 1 the invention system is applicable to detect transient/intermittent single phase to ground faults in a three-phase three-wire median voltage (10 kV-35 kV) electric power distribution system. To selectively alarm on the faulty feeder among all feeders 10 which are radially connected on a bus-bar 11, the neutral point of the system is ungrounded or is grounded at only one point 16, which is often in a substation via a transform. The detecting device 12, which is normally installed in the substation where the bus bar is installed, samples the residual current from CT (Current Transformer) 13 on one feeder and residual voltage from PT (Potential Transformer) 14 on busbar. It detects the transient grounding fault event 15 and identifys the direction of such event. The direction results are forward direction (from busbar to feeder) and reverse direction (from feeder to busbar). When the fault is on the feeder where the detector has been installed, a forward direction should be seen by the detector, while the fault is on the other feeders, a reverse direction or non-direction should seen by the detector. The detector alarms when an intermittent event (series of transient grounding events) with forward direction has been detected, indicating the substation personnel to check the status of the feeder where this alarmed detector has been installed.

The invention system is designed to directionally detect earth faults, especially the transient/intermittent ones which also cover a large portion of high impedance single phase to ground faults. It overcomes the difficulties that the conventional relays cannot rightly deal with the intermittent and transient events, and cannot rightly respond to said events. Therefore, it can be an improvement or a supplement for a conventional earth fault detection device.

The method and system of the invention have two main modules:

1) For a transient direction detection, it calculates the instantaneous power direction based on fault component residual current and fault component residual voltage. Indeed, in the fault component circuit, the active power flows from the bus-bar to the healthy line, and flows from the faulty line to the bus-bar. If the electric power distribution system is grounded via a resistor or is not grounded, the reactive power flows from the bus-bar to the faulty line and flows from the healthy line to the bus-bar. Therefore, a threshold of corresponding power component is set, and by comparing the calculated instantaneous power to the threshold, the algorithm gives out a direction result. Said active power and reactive power are obtained by using Hilbert transform based on instantaneous power for non-sinusoid signals. The advantage of using such instantaneous power direction enables the algorithm to output a valid direction result even for a fast transient event. As the instantaneous reactive power direction is mainly depending on the system characteristics (inductive or capacitive), making it a more robust feature, therefore the selectivity as well as the sensitivity can be increased.

2) For a random intermittent detection, it accumulates an average amplitude value in a pre-fault READY stage and calculates the incremental amplitude by subtracting the average amplitude from the full amplitude. At the beginning, the incremental amplitude is compared to a start threshold and triggers the module into START stage. Then, the detecting device begins by counting the changes of the amplitude status, which is the changes of status being above or below another burst threshold. Also if the direction module is enabled, the detecting device counts the changes with a specified direction. At the end of the preset detection time, the algorithm gives out a report according to the counting result. This increases the chances for the detecting device to capture those widely existing earth fault phenomena that conventional relay may not be able to respond to.

Advantageously, the invention system, as shown on FIG. 2, comprises:

a module 20 for sampling voltage and current,

a trigger 21,

an intermittent spike detection module 22,

a module 23 for adjusting a power threshold of transient direction detection,

an instantaneous power direction module 24,

a counter 25,

a module 26 giving out a report.

The invention method includes a transient direction detection (TDD) step and a random intermittent detection (RID) step. Both have three major stages:

a READY stage, when the algorithm keeps monitoring ready to be started;

a START stage when the algorithm begins to evaluate the fault; and

an ALARM/RESET stage, when the START stage ends, the algorithm gives out the result by alarm (fault confirmed) or reset (fault not confirmed). These two detection steps are analyzed below.

1) Transient Direction Detection (TDD)

The transient direction detection (TDD) has a pre-start buffer for updating two-cycle samples array of the residual current and residual voltage when the algorithm is in READY stage. Transient direction detection is started by trigger 21 by capturing the residual current's abrupt increase. When in START stage, transient direction detection firstly calculates the superimposed residual current and residual voltage by subtracting the points in the pre-start buffer of the second cycle in READY stage samples from the newly sampled residual current and residual voltage on the corresponding point. By using such superimposed current i(t) and voltage u(t), the transient direction detection calculates the instantaneous power:

For the active power, the instantaneous value is:

p(t)=u(t)·i(t)

The instantaneous active power is the average value of p(t) in previous one cycle T:

$$P = \frac{1}{T} {\int }_{t - T}^{t} p ( t ) \cdot d t$$

For the reactive power, the Hilbert transform is applied. the Hilbert transform by convolution is defined by the following function, p.v. representing Cauchy primary value:

$$h ( t ) = p . v . \frac{1}{π t}$$

Transient direction detection calculates:

The Hilbert transform of the residual voltage, convolution using Cauchy Primary Value Integral:

$${u}^{′} ( t ) = H ( u ) ( t ) = p . v . {\int }_{- ∞}^{+ ∞} u ( τ ) h ( t - τ ) d τ$$

Then, the instant value of the power by p′:

p′(t)=u′(t)·i(t)

The instantaneous reactive power is the average value of p′ in one cycle:

$$Q = \frac{1}{T} {\int }_{t - T}^{t} {p}^{′} ( t ) \cdot d t$$

Then, the direction criterion is, assuming the power direction is positive/forward when it flows from the bus-bar to the feeder:

a) In a system grounded via a resistor or ungrounded:

If Q is above the forward Q threshold (a positive value), direction is forward and fault is on this line;
Otherwise, direction is not on this line.

b) In a system grounded via a Peterson coil:

If P is below the forward P threshold (a negative value), direction is forward and fault is on this line;
Otherwise, direction is not on this line.

2) Random Intermittent Detection (RID)

The random intermittent detection is based on the changes of the incremental amplitude of the residual current. If the increment of the amplitude is greater than a predetermined threshold, the random intermittent detection assumes the fault is conducted. If said increment is below the threshold the random intermittent detection assumes the fault is extinguished. By counting such conducted-extinguished state changes of forward direction within a preset time duration, the algorithm gives out a set of results for confirmed earth faults, or transient events, steady events and noises.

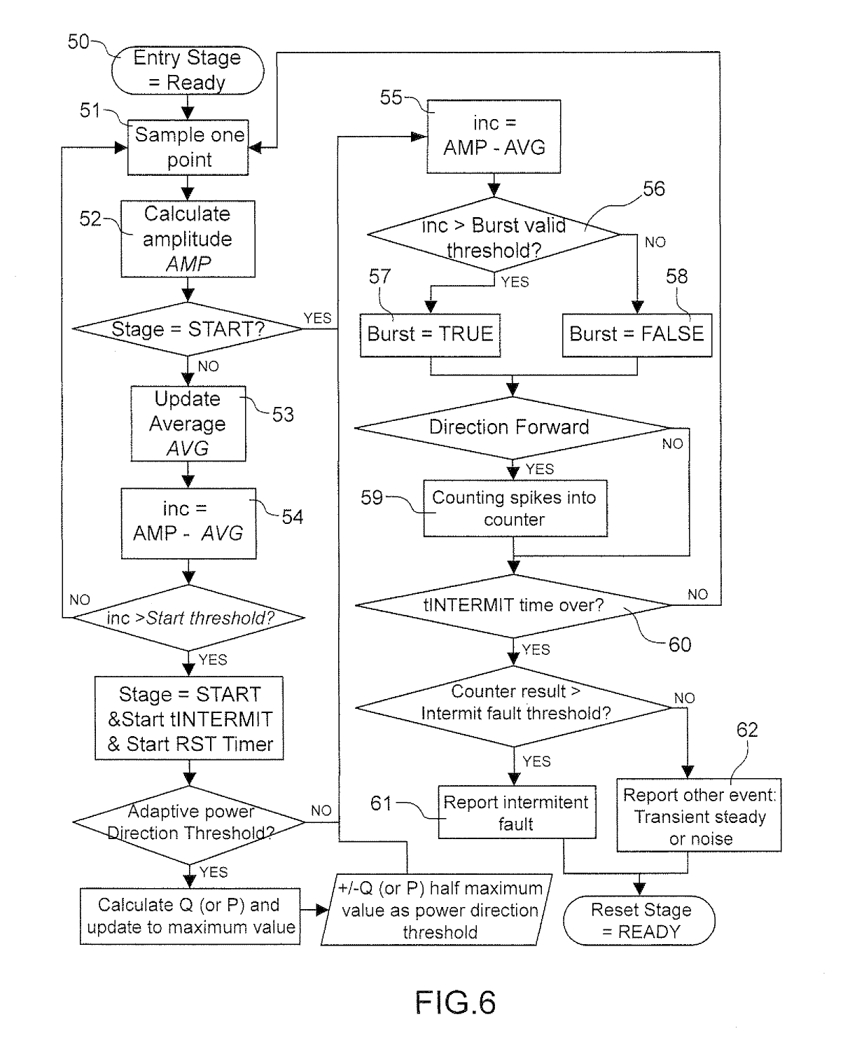

As shown on FIG. 6, in READY stage, the random intermittent detection keeps calculating the amplitude AMP (step 52) by using half-cycle R.M.S. (“Root Mean Square”) method. It then uses this value for updating an average amplitude value AVG (step 53) which is stored in a memory as a representation of the current condition of the residual current. By subtracting this average value from the newly calculated amplitude AMP, an increment value “inc” is obtained (step 54). In READY stage, the random intermittent detection compares “inc” to the start threshold to trigger a start signal, this signal is the trigger 21 in FIG. 2. In START stage, the average amplitude value AVG stops updating and keeps its latest value in READY stage. While increment “inc” is obtained by subtracting this average amplitude from newly calculated amplitude (step 55), another threshold, a burst threshold, is used for comparison. If the increment “inc” is greater than said burst threshold (step 56), random intermittent detection assumes the fault is conducted and sets the fault conducted status (“burst”) to “true” (57). If the incremental amplitude “inc” is lower than said burst threshold (step 56), random intermittent detection assumes the fault is extinguished and sets the fault conducted status (“burst”) to “false” (step 58). Random intermittent detection also keeps sampling the direction result of transient direction detection. A burst counter keeps counting the changes of such status changes of forward direction (step 59). At the end of the START stage (The timer: tINTERMIT times over; step 60), the result of this counter is then compared to a set of event thresholds. If intensive changes of fault conducted status are present, an intermittent earth fault result is issued (step 61). Otherwise, other results such as transient events (the result of the counter does change but does not exceed fault threshold), steady events (the amplitude only increase and keep above burst threshold) and noises are issued (step 62). In ALARM/RESET stage, the algorithm outputs the result, and discards the average amplitude and starts running all over again.

3) Extending Random Intermittent Detection to Address Intermittent Events

Another global reset timer is set to reset the entire algorithm. If a transient event is detected by random intermittent detection and transient direction detection at the end of the START stage, the algorithm keeps waiting for further events. If consecutive three transient events are detected within such reset time duration, an intermittent earth fault will also be reported.

4) Transient Direction Detection Adaptive Threshold Setting

A facility algorithm tracks the maximum absolute value of the calculated power by transient direction detection and automatically sets the P or Q thresholds to half of their maximum values. The algorithm is started with random intermittent detection and transient direction detection, and adaptively changes the direction thresholds in 1) to enable the direction algorithm giving out a definite direction result when a transient event has been captured by random intermittent detection, and also to rule out any possible noises and distortion of the transient direction detection.

### A Preferred Embodiment

In said preferred embodiment, random intermittent detection and transient direction detection are implemented into a sampling and alarming device. Said device keeps sampling the residual current and the residual voltage of a feeder. The residual value can be directly obtained from a transformer for a residual value or can be derived from a phase value. Said device performs the algorithm in real time. It executes the algorithm every half power cycle. Said device is able to track the power frequency and to adjust its sampling rate to exactly N points per cycle (for example N=24 in this device). Moreover, it is able to retrieve the history sample value at every execution point.

### 1. Implementation of the Transient Direction Detection (TDD) method

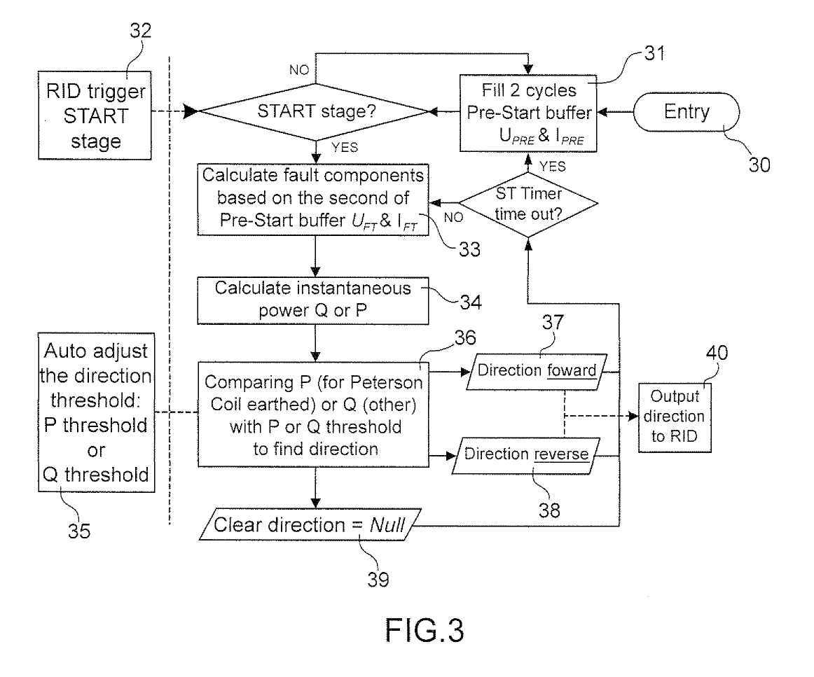

As shown on FIG. 3, after the entry (30), transient direction detection keeps filling a two-cycle length pre-fault buffer (step 31), when it is in READY stage. When random intermittent detection sets the detecting device into START stage (step 32), the transient direction detection moves the second pre-fault cycle into a buffer, and by subtracting this second pre-fault cycle from full sampled current and voltage at every execution point, the fault current and voltage component is obtained (step 33). The fault current and voltage component is the input value of the transient direction detection algorithm. If the detecting device is configured to use the reactive power direction (which is recommended for the system with neutral point grounded via a resistor or isolated) at every half cycle, the Hilbert transform is applied on fault component voltage of the previous two-cycle array. Practically, the Hilbert transform is applied by convolution summation (symbole “*”) of the digital Hilbert coefficient with the input sample signals:

DHT(x)[n]=h[n]*x[n]

where:

$$h [ n ] = \{ \begin{matrix}0 & n is even \\ \frac{2}{n π} & n is odd\end{matrix} - N < n < N$$

With respect to the Hilbert transform, a 48 points buffer stores two cycles of history sample data as the input x[n] array. After the Hilbert transform is applied, the 24 points in the middle of the result array UN are taken as the Hilbert transform result. Two cycles of residual voltage UN are the input signal. Therefore one cycle UN′ (in the middle of the convolution result) is the Hilbert transform result. Product of UN′ and of residual current IN's corresponding points produces the instant reactive power array q[n]. The average value of q[n] array of one previous cycle (instantaneous reactive power Q) is used to detect the fault direction in a neutral point resistor grounded or isolated system. Product of UN and of residual current IN's corresponding points produces the instant active power array p[n]. The average value of p[n] array in one previous cycle (instantaneous active power P) is used to detect the fault direction in a neutral point Peterson coil grounded system. Therefore instantaneous powers P or Q are calculated (step 34).

Although the direction can be represented by the symbols of the calculated power, a threshold is set to rule out possible noise interferences. In a threshold setting (step 35), a power threshold is set to detect the direction. When using reactive power, if the calculated reactive power Q is greater than the forward +Q threshold (step 36) a forward direction is set (step 37). If the calculated reactive power is less than −Q threshold (step 36), a reverse direction flag is set. When using active power, if the calculated active power P is less than −P threshold a forward direction flag is set. If the calculated active power is above the +P threshold a reverse direction flag is set (step 38). Step 39 shows a clear direction (=Null). Step 40 shows output direction to random intermittent detection (RID).

Said thresholds can be set by two means:

a) Fixed Threshold:

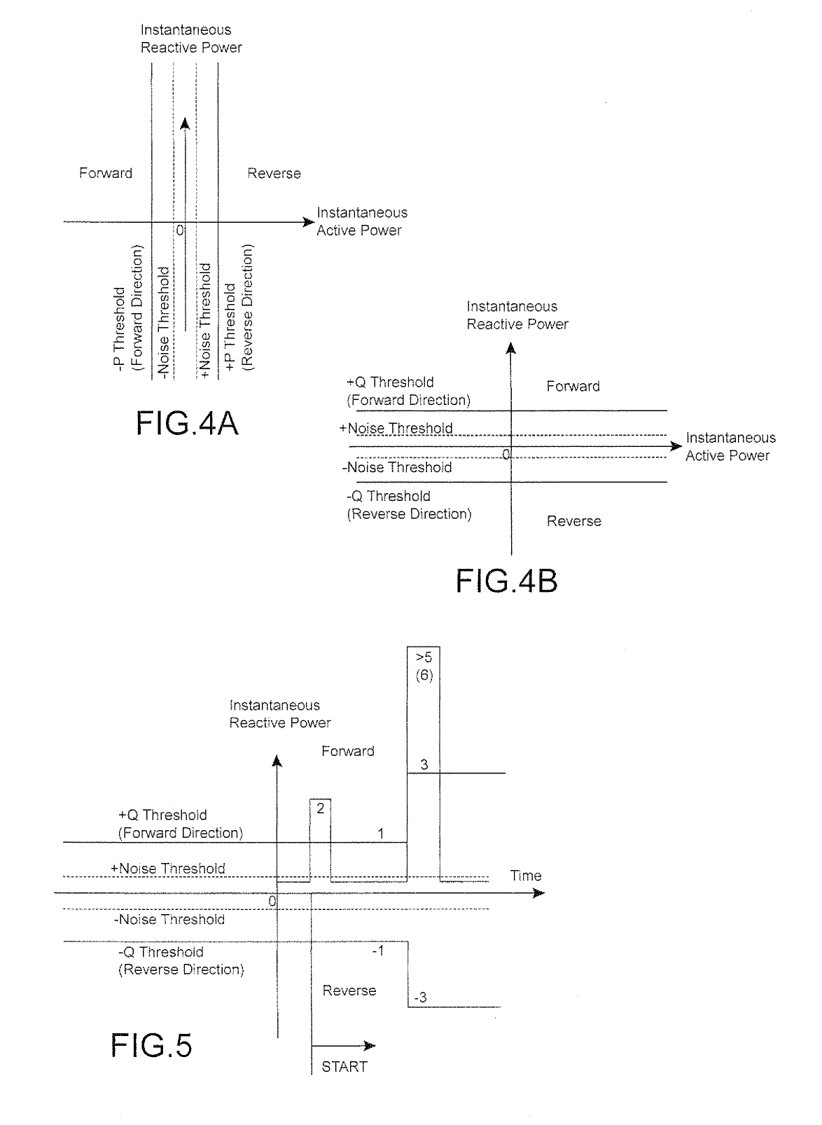

A fixed threshold is a power threshold for direction detection. As shown in FIG. 4B, if using reactive power, a Q threshold (for forward direction) is set. If calculated instantaneous reactive power is greater than +Q threshold, a forward direction flag is issued. If the calculated instantaneous reactive power is less than the +Noise threshold, then the forward direction flag is cleared. If the calculated reactive power is negative and below −Q threshold, a reverse direction is set. If the calculated reactive power is greater than −Noise threshold, then a reverse direction flag is cleared. As shown on FIG. 4A, if using active power, a P threshold (for reverse direction) is set. If calculated instantaneous active power is greater than +P threshold, a reverse direction flag is set. If calculated instantaneous active power is less than +Noise threshold, the reverse flag is cleared, forward direction is obtained.

b) Adaptive Threshold:

An adaptive threshold is adjusting itself according to the amplitude/power conditions. In START stage, when a transient fault conducting state is confirmed by random intermittent detection for the first time, the transient direction detection takes half of the absolute value of the instantaneous power as the threshold (P or Q thresholds). Then if another instantaneous power value is much greater (said absolute value is five times greater than the P or Q thresholds), half of the greatest instantaneous power absolute value is taken as the new threshold. Therefore, in the START stage of the algorithm, transient direction detection seeks the greater value of the instantaneous power within the START time duration and automatically sets the threshold according to the value of this power. This is to ensure that the transient direction detection gives a definite result of direction and also to avoid noise interferences.

Adaptive threshold is recommended to be used with reactive instantaneous power direction detection. An example is show in FIG. 5. When in START stage, the instantaneous power of the first transient spike is ‘2’, then Q threshold is set to ‘1’, the second power spike is ‘6’ which is much (five times) greater than the older Q threshold, so the Q threshold is changed to half of it, therefore 3 is the new Q threshold.

### 2. Implementation of the Random Intermittent Detection (RID) Method

As shown on FIG. 6, after entry 50, the random intermittent detection method samples the residual current (step 51) or derives the residual current from phase current. The random intermittent detection is the main algorithm that triggers the detection duration (by triggering the START stage) and gives out the fault detection result. In the READY stage, the random intermittent detection calculates the following values:

1) The average amplitude y(n) of the residual of previous N points, is obtained by a filter:

y(n)=[y(n−1)·(N−1)+x(n)]/N

where n is the currently sampling/calculating point; N is the total length that the average value represents; N is settable, and here N=24×50×10 represents previous 10 seconds history value. y(n) is the current average amplitude on current time point, and represents previous N points amplitude conditions. y(n−1) is the average amplitude of the previous point. x(n) is the newly calculated full amplitude according to the previous half-cycle of the sampled residual current. In normal running stage the filter is applied to update the average condition of the residual amplitude. But in fault evaluation stage, the average amplitude is kept unchanged representing the amplitude condition of the prestart stage.

2) The incremental amplitude “inc(n)” is such that:

inc(n)=x(n)−y(n−1).

In the READY stage, the random intermittent detection compares “inc(n)” to the start threshold to trigger a start signal and to put random intermittent detection and transient direction detection into the START stage. The amplitude is based on half-cycle Fourier or R.M.S. calculation result. If “inc(n)” exceeds the start threshold, the algorithm enters the START stage. A global reset timer ‘RST timer’ starts. The duration is 30 seconds. The entire algorithm is reset at the end of RST timer if it is not reset by other means.

In the START stage, the average value as well as the pre-start sample array is kept (stop updating). The incremental amplitude “inc(n)” is obtained by inc(n)=x(n)−y(n−1). But y(n−1) is locked to the latest pre-start value. In the START stage, a burst threshold is set. When the incremental amplitude “inc(n)” is greater than the burst threshold, the fault is assumed to be conducted. Once the residual current is below the burst threshold, the fault is extinguished. A consecutive conducting and extinguishing forms a spike. Random intermittent detection counts such spikes within a preset time duration, which is fixed by a timer called tINTERMIT (to evaluate intermittent events). Said timer is started once the incremental amplitude value “inc(n)” of the residual current is above the burst threshold. When the timer tINTERMIT is timing, a counter begins counting the spikes. At the end of the preset time duration, the value of the counter is compared to a set of threshold. In this example, if within 5 seconds (tINTERMIT duration), up to 10 spikes have been captured by the counter, an intermittent fault is reported. If only several (up to 3) spikes have been captured by the counter, a transient event is reported. If only one or two spikes have been captured, they are ignored as noises. If the incremental amplitude “inc(n)” stays above the burst threshold for the entire preset time duration, a steady event is then reported.

### 3. Integration of Random Intermittent Detection and Transient Direction Detection

The integration of the transient direction detection and random intermittent detection consists of two parts: in the START stage and in the detection result report.

In the START stage, the integration is as shown in FIG. 2: The counter 25 of the random intermittent detection only counts the spikes with forward direction result from the transient direction detection for the fault evaluation, therefore ruling out the interferences of the fault interference on healthy lines.

In the detection result report 26, the detailed implementation is as follows:
If the result is intermittent fault, then report and alarm and reset entire algorithm.
If the result is noises or steady event, then ignore, do nothing.
If the result is transient event, then algorithm continues in the START stage and waits for further event until entire algorithm is reset by RST timer.
If at the end of RST timer, up to 3 transient events have been spotted, then report as intermittent fault, alarm and reset.

### 4. Examples

The invention has been implemented into MiCOM P145 relay as a prototype model and has been tested by both physical model and digital simulation:

It can selectively alarm on a faulty line and restraint on healthy line in case of intermittent fault. The physical system is earthed via a resistor.

b. Positive results have been obtained from digital simulation (EMTP (“Electromagnetic transient program”) Test) with various cases including all kinds of grounding conditions. RTDS (“Real True Digital Simulator”) simulation has also been planned. The principle of RTDS and EMTP is the same.

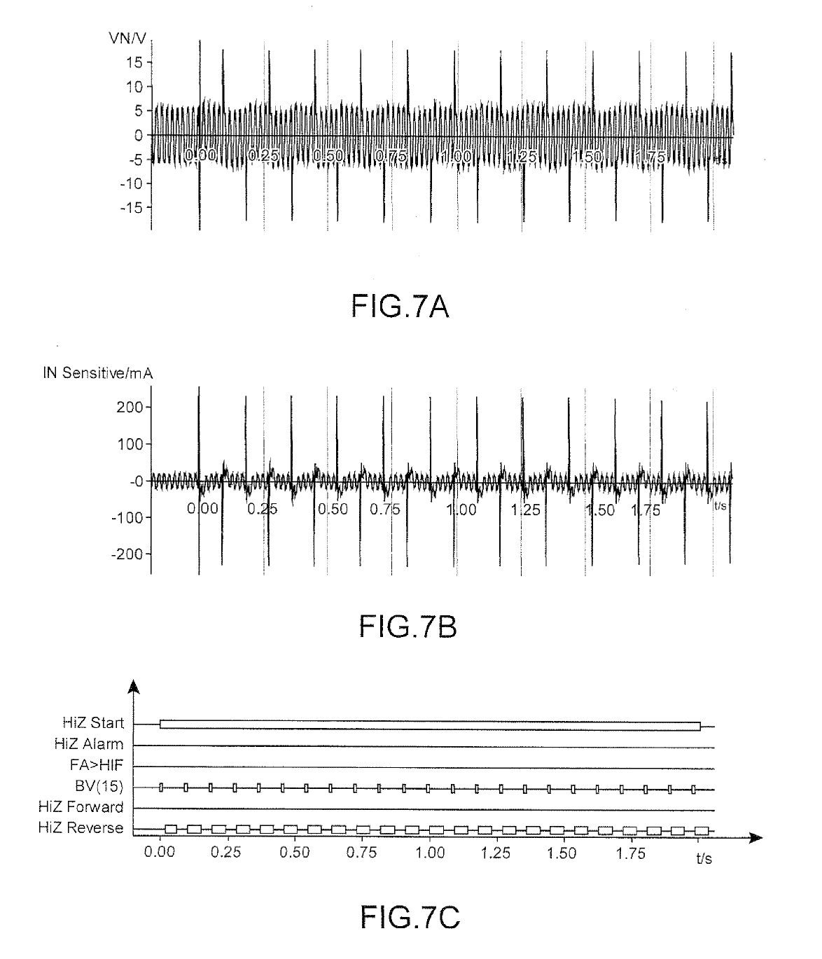

An exemplary result from the physical model is as shown on FIGS. 7A, 7B and 7C when the prototype relay is installed on a healthy line. The system is earthed via a resistor to restrict the fault current. An intermittent earth fault also causes intensive disturbance on a healthy line: FIG. 7A shows the sampled residual voltage's waveform labelled with “VN”, and FIG. 7B shows residual current's waveform labeled with “IN Sensitive”. All sampled value are from the secondary side of the relay, FIG. 7C shows relay's responses. The spikes are identified by comparing amplitude's increment to a threshold and indicated by “By”. The direction result “HiZ_Reverse” and “HiZ_Forward” are obtained by using the instantaneous reactive power's direction. “HiZ Start” indicates the algorithm is in START stage. “HiZ Alarm” is the alarming result. “FA>HIF” means the alarm is triggered by this RID module. The algorithm has been able to selectively count the spikes. Therefore, there is no alarm in this situation because all the spikes are identified in the reverse direction with “HiZ_Reverse”.

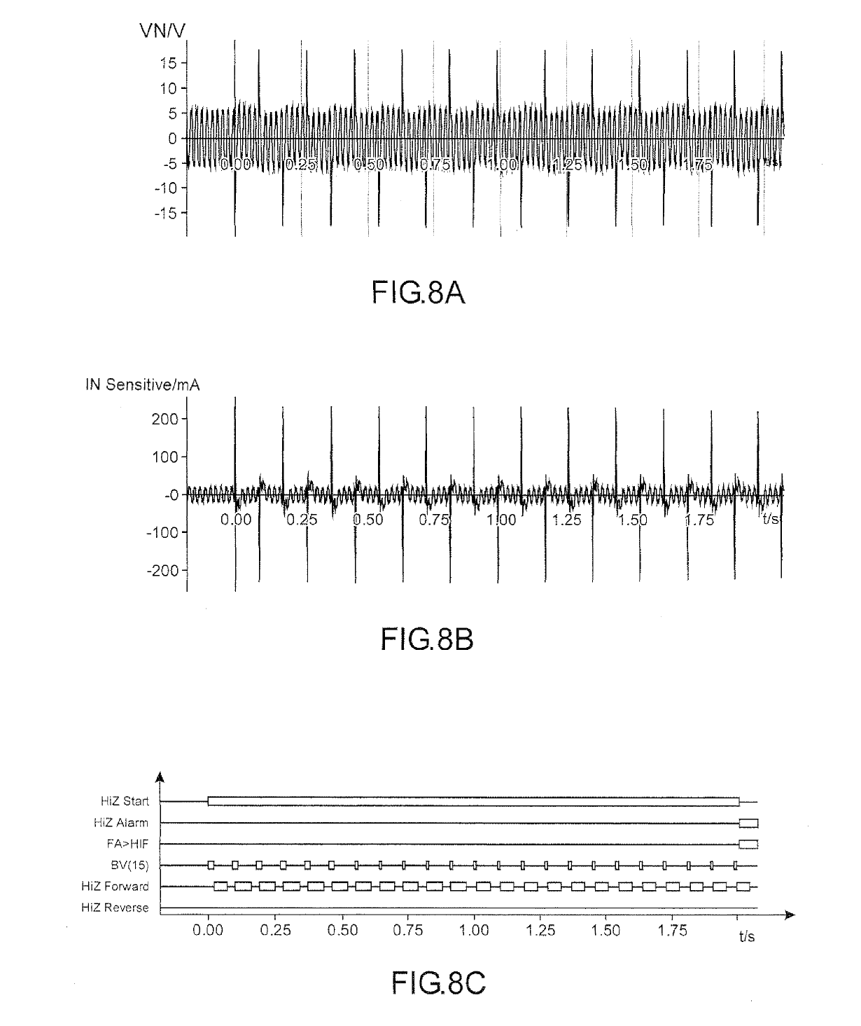

An exemplary result from the physical model is as shown on FIGS. 8A, 8B and 8C in the same way as in FIGS. 7A, 7B and 7C. The prototype relay is installed on a faulty line. The spikes with forward direction “HiZ_Forward” are counted and then the algorithm alarms on this faulty line due to the number of forward spikes exceeds the threshold.

### REFERENCES

[1] US 2008/0031520
[2] U.S. Pat. No. 5,485,093
[3] WO 2005 038474
[4] EP 0 999 633

1. A method for transient/intermittent earth fault detection and direction determination in a three-phase median voltage electric power distribution system which comprises many lines, which comprises, for one line:
a sampling step wherein the residual current and the residual voltage on said line are sampled, in tracking the power frequency and in adjusting the sampling rate to N points per cycle, N being an integer.
a transient direction detection step comprising:
in a ready stage,
updating samples of the residual current and the residual voltage in a buffer,
in a start stage,
calculating the superimposed residual current and residual voltage by substracting a point in the buffer from the newly corresponding sampled residual current and residual voltage,
calculating the instantaneous power direction based on superimposed residual current and residual voltage,
giving out a direction result by comparing the calculated instantaneous power to a power threshold,
a random intermittent detection step comprising:
in a ready stage,
accumulating an average amplitude value,
calculating an incremental amplitude by substracting the average value from the full amplitude,
in a start stage,
comparing the incremental amplitude to a bust threshold, a fault being assumes to be conducted if the incremental amplitude is greater than the burst threshold,
a step of integrating transient direction detection and random intermittent detection comprising:
counting the number of consecutive conducting and extinguishing, forming spikes, in counting only the spikes with forward direction result from the transient direction detection step for the fault evaluation,
comparing the value obtained at the end of a preset time to many thresholds so that a result is obtained: it is an intermittent fault, a transient event or a steady event,
a step of giving out the result by alarm or reset in the following way:
if the result is intermittent fault, then report and alarm and reset,
if the result is noises or steady event, then ignore, do nothing,
if the result is transient event, then continue in the START stage and wait for further event until reset at the end the preset time,
if at the end of the preset time, up to three transient events have been spotted, then report as intermittent fault, alarm and reset.

2. The method according to claim 1, wherein the transient direction detection step and the random intermittent detection step have the following stages:
a READY stage, when the algorithm keeps monitoring and is ready to be started;
a START stage when the algorithm begins to evaluate the fault; and
an ALARM/RESET stage, occurring when the START stage ends, wherein the result by alarm or reset is given out.

3. The method according to claim 2, wherein if a transient event is detected by random intermittent detection and transient direction detection at the end of the START stage, further events are expected, and if consecutive three transient events are detected within a reset time duration, an intermittent earth fault is reported.

4. The method according to claim 1, wherein the instantaneous active or reactive power is used for direction detection.

5. The method according to claim 1, wherein fault components of residual current and residual voltage are used to calculate the instantaneous power.

6. The method according to claim 5, wherein the Hilbert transform based on instantaneous power is used.

7. The method according to claim 6, wherein the instantaneous active power is obtained by averaging instant residual voltage and residual current's scalar multiplication in previous one cycle time window, while the instantaneous reactive power is obtained by averaging Hilbert transformed instant residual voltage's and residual current's scalar multiplication in previous one cycle time window, the direction discrimination being performed by comparing such instantaneous active power or such instantaneous reactive power to a power threshold.

8. The method according to claim 5, which keeps sampling and buffering the samples of the residual current and residual voltage in the normal running stage (READY stage), and these normal samples will be kept in fault evaluation stage (START stage), the fault component being obtained by substracting these normal samples from the full samples in START stage and the fault components being used for instantaneous power calculation and further direction detection.

9. The method according to claim 5, wherein, in the fault component circuit, assuming the direction from the bus-bar to the feeder is the positive/forward direction, a power threshold is predetermined.

10. The method according to claim 9, wherein, if the active instantaneous power is negative and falls below the negative value of a power threshold, a forward direction is then issued, if the active instantaneous power is positive and is greater than the positive value of active power threshold, a reverse direction is then issued.

11. The method according to claim 9, wherein, if the reactive instantaneous power is positive and greater than the positive reactive power threshold a forward direction result is then issued; if the reactive instantaneous power is negative and below the negative value of the reactive power threshold then a reverse direction result is issued.

12. The method according to claim 9, comprising a fault evaluation step, wherein the direction is given by comparing the calculated instantaneous power with a power threshold, the power threshold being adaptively changing according to the maximum value of the calculated power.

13. The method according to claim 12, wherein the power threshold is set to half of the maximum calculated power absolute value.

14. The method according to claim 13, wherein if the instantaneous power value is such than its absolute value is five times greater than the P or Q's current thresholds, half of the greatest instantaneous power absolute value is considered as the new threshold.

15. The method according to claim 1, wherein incremental amplitude is used to detect intermittent spikes, and to initiate fault evaluation, the amplitude being computed by using half-cycle R.M.S. calculation.

16. The method according to claim 15, wherein the spike's direction is obtained from transient direction detection step, when fault evaluation is initiated within a settable detection time, said spikes with forward direction being counted, the results at the end of the fault evaluation time being used to compare to specified thresholds.

17. The method according to claim 15, wherein incremental amplitude is obtained by subtracting the average amplitude from the newly calculated amplitude, the average amplitude being obtained by a filter: y(n)=[y(n−1)·(N−1)+x(n)]/N, where y(n) is the average amplitude on a current time point, and represents previous N points amplitude conditions, y(n−1) is the average amplitude of the previous point, x(n) is the newly calculated amplitude.

18. The method according to claim 15, wherein, at the end of fault evaluation, if the numbers of spikes counted exceeds a determined level, the result indicates an intermittent fault; if the number of spikes is more than 2 but is below the determined level, a transient event is reported; if the amplitude keeps increasing or remain unchanged without decrease, a steady event is the result; other situations being reported as noises.

19. A system for transient/intermittent earth fault detection and direction determination in a three-phase median voltage electric power distribution system which comprises many lines, which comprises:
sampling means wherein the residual current and residual voltage on said lines are sampled, in tracking the power frequency and in adjusting the sampling rate to exactly N points per cycle, N being an integer,
transient direction detection means, which implement:
in a ready stage,
updating samples of the residual current and the residual voltage in a buffer,
in a start stage,
calculating the superimposed residual current and residual voltage by substracting a point in the buffer from the newly corresponding sampled residual current and residual voltage,
calculating the instantaneous power direction based on superimposed residual current and residual voltage,
giving out a direction result by comparing the calculated instantaneous power to a power threshold,
random intermittent detection means, which implement:
in a ready stage,
accumulating an average amplitude value,
calculating an incremental amplitude by substracting average value from the full amplitude,
in a start stage,
comparing the incremental amplitude to a burst threshold, a fault being assumed to be conducted if the incremental amplitude is eater than the burst threshold,
means of integrating transient direction detection and random intermittent detection, which implement:
starting a counter and counting the number of consecutive conducting and extinguishing, forming spikes, in counting only the spikes with forward direction result from the transient direction detection means,
comparing the value obtained at the end of a preset time to many thresholds so that a result is obtained: it is an intermittent fault, a transient event or a steady event,
means of giving out the result by alarm or reset which implement:
if the result is intermittent fault, then report and alarm and reset,
if the result is noises or steady event, then ignore, do nothing,
if the result is transient event, then continue in the START stage and wait for further event until reset by the counter,
if at the end of the preset time, up to three transient events have been spotted, then report as intermittent fault, alarm and reset.

20. The system according to claim 19, which comprises:
a module for sampling voltage and current,
a trigger,
an intermittent spike detection module,
a module for adjusting a power threshold of transient direction detection,
an instantaneous power direction module,
a counter,
a module giving out a report.
